(19) United States
(12) Patent Application Publication
(10) Pub. No.: US 2026/0068251 A1
(43) Pub. Date: Mar. 5, 2026

(54) SEMICONDUCTOR DEVICES

(71) Applicant: Samsung Electronics Co., Ltd., Suwon-si (KR)

(72) Inventors: Gyeom Kim, Suwon-si (KR); Seok Hoon Kim, Suwon-si (KR); Yong Jun Nam, Suwon-si (KR); Pan Kwi Park, Suwon-si (KR); Hyo Hoon Byeon, Suwon-si (KR)

(21) Appl. No.: 19/019,965

(22) Filed: Jan. 14, 2025

(30) Foreign Application Priority Data
Aug. 28, 2024 (KR) 10-2024-0116061

(51) Int. Cl. H10D 62/13; H10D 30/00; H10D 30/01; H10D 62/00; H10D 84/85

(52) U.S. Cl. CPC H10D 62/151; H10D 30/019; H10D 30/501; H10D 62/021; H10D 84/851

(57) ABSTRACT

A semiconductor device is provided. The semiconductor device comprises an active pattern on a substrate, the active pattern including a lower pattern that extends in a first direction, and sheet patterns that are spaced apart from the lower pattern in a second direction; a source/drain pattern on the lower pattern and in contact with the sheet patterns; and a gate structure on a side of the source/drain pattern, and including a gate insulating film and a gate electrode, wherein the source/drain pattern includes a first semiconductor material film in contact with each of the sheet patterns, a second semiconductor material film on the first semiconductor material film, and a third semiconductor material film on the second semiconductor material film, the first semiconductor material film has a monocrystalline structure, the second semiconductor material film has a polycrystalline structure, and the third semiconductor material film has an amorphous structure.

### CROSS-REFERENCE TO RELATED APPLICATIONS

This application claims priority from Korean Patent Application No. 10-2024-0116061 filed on Aug. 28, 2024 in the Korean Intellectual Property Office, and all the benefits accruing therefrom under 35 U.S.C. 119, the contents of which in its entirety are herein incorporated by reference.

### BACKGROUND OF THE INVENTION

The present disclosure relates to a semiconductor device.

Multi-gate transistors have been proposed as one of the scaling technologies to increase the density of semiconductor devices. The multi-gate transistors may be obtained by forming multi-channel active patterns (or silicon bodies) in the shape of fins or nanowires on a substrate and then forming gates on the surfaces of the multi-channel active patterns.

The multi-gate transistors may be easier to scale due to their utilization of three-dimensional (3D) channels. Additionally, the multi-gate transistors may improve current control capabilities without increasing their gate length. Moreover, the multi-gate transistors may effectively suppress the short channel effect (SCE), where the potential in a channel area is affected by the drain voltage.

### SUMMARY OF THE INVENTION

Aspects of the present disclosure provide a semiconductor device with improved device performance and reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to embodiments of the present disclosure, there is provided a semiconductor device comprising an active pattern on a substrate, the active pattern including a lower pattern that extends in a first direction parallel to an upper surface of the substrate, and a plurality of sheet patterns that are spaced apart from the lower pattern in a second direction perpendicular to the first direction; a source/drain pattern on the lower pattern and in contact with the plurality of sheet patterns; and a gate structure on a side of the source/drain pattern, and including a gate insulating film and a gate electrode, wherein the source/drain pattern includes a first semiconductor material film in contact with each of the plurality of sheet patterns, a second semiconductor material film on the first semiconductor material film, and a third semiconductor material film on the second semiconductor material film, wherein the first semiconductor material film has a monocrystalline structure, wherein the second semiconductor material film has a polycrystalline structure, and wherein the third semiconductor material film has an amorphous structure.

According to the aforementioned and other embodiments of the present disclosure, there is provided a semiconductor device comprising an active pattern on a substrate, the active pattern including a lower pattern that extends in a first direction parallel to an upper surface of the substrate, and a plurality of sheet patterns that are spaced apart from the lower pattern in a second direction perpendicular to the first direction; a source/drain pattern on the lower pattern and in contact with the plurality of sheet patterns; and a gate structure on a side of the source/drain pattern, and including a gate insulating film and a gate electrode that extends in a third direction crossing the first direction, wherein the source/drain pattern includes a first semiconductor material film in contact with each of the plurality of sheet patterns and a second semiconductor material film on the first semiconductor material film, wherein the first semiconductor material film has a monocrystalline structure, wherein the second semiconductor material film has an amorphous structure, and wherein in a cross-sectional view, the second semiconductor material film includes sidewalls that extend in the second direction.

According to the aforementioned and other embodiments of the present disclosure, there is provided a semiconductor device comprising a first active pattern on a substrate, the active pattern including a first lower pattern that extends in a first direction parallel to an upper surface of the substrate, and a plurality of first sheet patterns that are spaced apart from the first lower pattern in a second direction perpendicular to the first direction; a second active pattern on the substrate, the second active pattern including a second lower pattern that extends in the first direction, and a plurality of second sheet patterns that are spaced apart from the second lower pattern in the second direction; a first source/drain pattern on the first lower pattern and in contact with the plurality of first sheet patterns; a second source/drain pattern on the second lower pattern and in contact with the plurality of second sheet patterns; a first gate structure on a side of the first source/drain pattern; and a second gate structure on a side of the second source/drain pattern, wherein the first source/drain pattern includes a first semiconductor material film in contact with each of the plurality of first sheet patterns, and a second semiconductor material film on the first semiconductor material film, wherein the first semiconductor material film has a monocrystalline structure, wherein the second semiconductor material film has an amorphous structure, and wherein the second source/drain pattern has a monocrystalline structure.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, in which:

FIG. 1 is an example plan view illustrating a semiconductor device according to some embodiments.

FIGS. 2, 3, and 4 are cross-sectional views taken along lines A-A, B-B, and C-C, respectively, of FIG. 1.

FIGS. 5 and 6 are diagrams illustrating a semiconductor device according to some embodiments.

FIGS. 7 and 8 are diagrams illustrating a semiconductor device according to some embodiments.

FIGS. 9 and 10 are diagrams illustrating a semiconductor device according to some embodiments.

FIGS. 11 and 12 are diagrams illustrating a semiconductor device according to some embodiments.

FIGS. 13 and 14 are diagrams illustrating a semiconductor device according to some embodiments.

FIG. 15 is a diagram illustrating a semiconductor device according to some embodiments.

FIG. 16 is an example plan view illustrating a semiconductor device according to some embodiments.

FIG. 17 is a cross-sectional view taken along line D-D of FIG. 16.

FIGS. 18 through 24 are diagrams illustrating intermediate steps of a method of manufacturing a semiconductor device according to some embodiments.

### DETAILED DESCRIPTION

In the accompanying drawings related to semiconductor devices according to some embodiments, various types of transistors are exemplified, including transistors including nanowires or nanosheets or Multi-Bridge Channel Field Effect Transistors (MBCFETs™), but the present disclosure is not limited thereto. The semiconductor devices according to some embodiments may also be applicable to Fin Field-Effect Transistors (FinFETs) with fin-shaped patterned channel areas.

The semiconductor devices according to some embodiments may include tunneling Field-Effect Transistors (FETs), three-dimensional (3D) transistors, or vertical FETs, and may also include planar transistors. Additionally, the technical concept of the present disclosure can be applied to transistors based on two-dimensional (2D) materials and their heterostructures.

Furthermore, the semiconductor devices according to some embodiments may also include bipolar junction transistors and Lateral Diffused Metal Oxide Semiconductor (LDMOS) transistors.

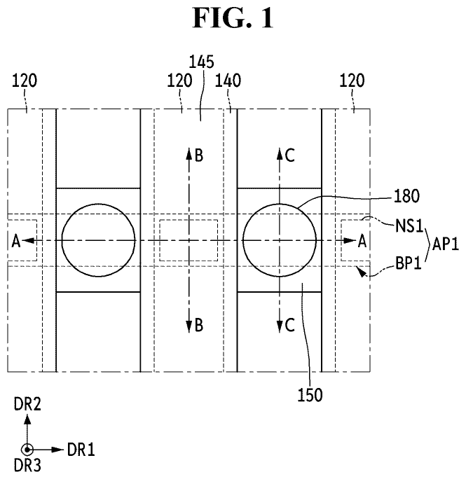

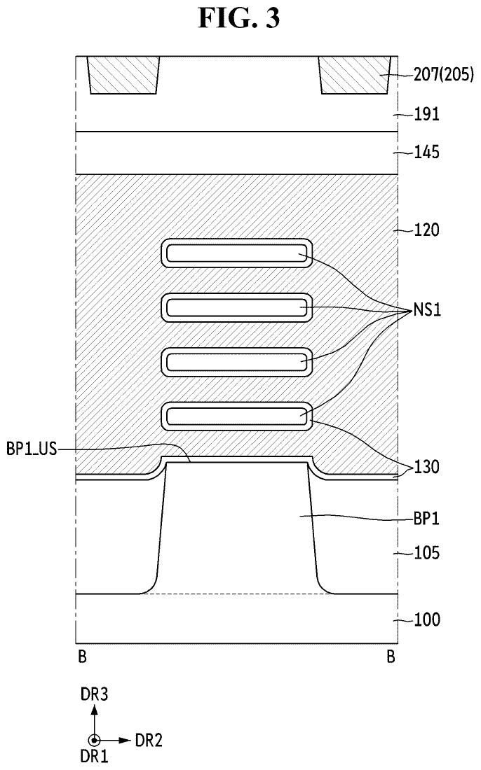

A semiconductor device according to some embodiments will hereinafter be described with reference to FIGS. 1 through 4.

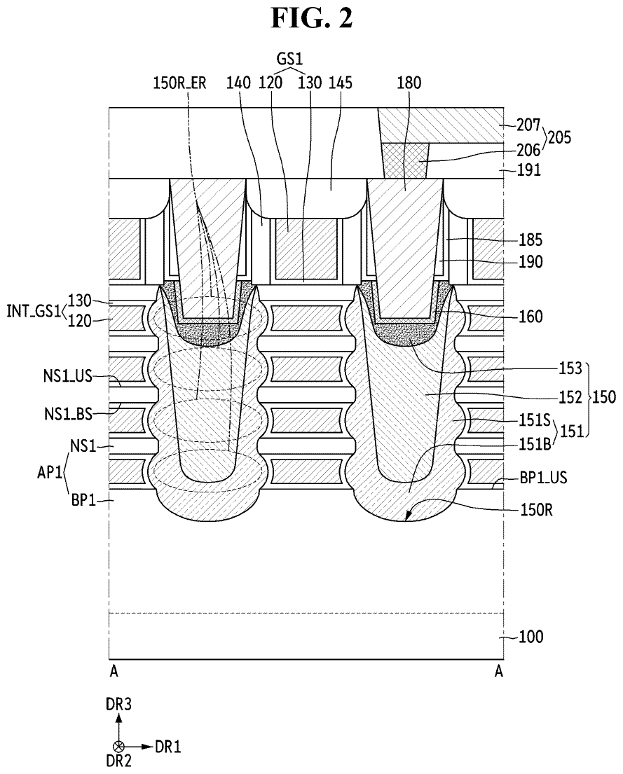

FIG. 1 is an example plan view illustrating a semiconductor device according to some embodiments. FIGS. 2, 3, and 4 are cross-sectional views taken along lines A-A, B-B, and C-C, respectively, of FIG. 1.

For reference, FIG. 1 is a simplified diagram of the semiconductor device according to some embodiments, omitting a first gate insulating film 130, a source/drain etch stop film 185, an interlayer insulating film 190, a wiring structure 205, etc. In FIG. 1, first source/drain contacts 180 are illustrated as being circular in a plan view, but the present disclosure is not limited thereto.

Referring to FIGS. 1 through 4, the semiconductor device according to some embodiments may include a first active pattern AP1, a plurality of first gate structures GS1, and first source/drain patterns 150.

A substrate 100 may be a bulk silicon or silicon-on-insulator (SOI) substrate. In some embodiments, the substrate 100 may be a silicon (Si) substrate or may include other materials, such as silicon-germanium (SiGe), SiGe-on-insulator (SGOI), indium antimonide, a lead telluride compound, indium arsenide, indium phosphide, gallium arsenide, or gallium antimonide, but the present disclosure is not limited thereto.

The first active pattern AP1 may be disposed on the substrate 100. The first active pattern AP1 may extend in a first direction DR1.

In one example, the first active pattern AP1 may be disposed in a region where P-type metal-oxide semiconductor (PMOS) transistors are formed. In another example, the first active pattern AP1 may be disposed in a region where N-type metal-oxide semiconductor (NMOS) transistors are formed.

The first active pattern AP1 may be, for example, a multi-channel active pattern. The first active pattern AP1 may include a first lower pattern BP1 and a plurality of first sheet patterns NS1.

The first lower pattern BP1 may protrude from the substrate 100. The first lower pattern BP1 may extend in the first direction DR1.

The first sheet patterns NS1 may be disposed on an upper surface BP1_US of the first lower pattern BP1. The first sheet patterns NS1 may be spaced apart from the first lower pattern BP1 in a third direction DR3. The first sheet patterns NS1 may be spaced apart in the third direction DR3.

Each of the first sheet patterns NS1 may include an upper surface NS1_US and a lower surface NS1_BS. The upper surfaces NS1_US of the first sheet patterns NS1 may be opposite to the respective lower surfaces NS1_BS of the first sheet patterns NS1 in the third direction DR3. The third direction DR3 may intersect the first direction DR1 and a second direction DR2. For example, the first and second directions DR1 and DR2 may each be parallel to an upper surface of the substrate 100 and may each be perpendicular to the third direction DR3. The third direction DR3 may be the thickness direction of the substrate 100. In other words, the third direction DR3 may be perpendicular to the upper surface of the substrate 100. The first direction DR1 may intersect the second direction DR2. For example, the first direction DR1 may be perpendicular to the second direction DR2.

Four first sheet patterns NS1 may be disposed in the third direction DR3, but the present disclosure is not limited thereto. The upper surface of the first active pattern AP1 may correspond to the upper surface NS1_US of an uppermost first sheet pattern NS1 among the first sheet patterns NS1.

The first lower pattern BP1 may be formed by etching a portion of the substrate 100, or may include an epitaxial layer grown from the substrate 100. The first lower pattern BP1 may include an elemental semiconductor material such as Si or germanium (Ge). Additionally, the first lower pattern BP1 may include a compound semiconductor, for example, a Group IV-IV compound semiconductor or a Group III-V compound semiconductor.

The Group IV-IV compound semiconductor may include a binary or ternary compound including at least two of carbon (C), Si, Ge, and tin (Sn), or a compound obtained by doping the binary or ternary compound with a Group IV element.

The Group III-V compound semiconductor may include a binary, ternary, or quaternary compound formed by combining at least one Group III element such as aluminum (Al), gallium (Ga), or indium (In) with one Group V element such as phosphorus (P), arsenic (As), or antimony (Sb).

The first sheet patterns NS1 may include an elemental semiconductor material such as silicon or germanium, a Group IV-IV compound semiconductor, or a Group III-V compound semiconductor. The first sheet patterns NS1 may include the same material as or a different material from the first lower pattern BP1.

In the semiconductor device according to some embodiments, the first lower pattern BP1 may be an Si lower fin-type pattern including Si, and the first sheet patterns NS1 may be Si sheet patterns including Si.

The width, in the second direction DR2, of the first sheet patterns NS1 may increase or decrease proportionally to the width, in the second direction DR2, of the first lower pattern BP1. In one example, first sheet patterns NS1 that are stacked in the third direction DR3 may all have the same width in the second direction DR2, but the present disclosure is not limited thereto. In some other embodiments, the width, in the second direction DR2, of the first sheet patterns NS1 that are stacked in the third direction DR3 may decrease away from the first lower pattern BP1.

A field insulating film 105 may be disposed on the substrate 100. The field insulating film 105 may be disposed on the sidewalls of the first lower pattern BP1. The field insulating film 105 may not disposed on the upper surface BP1_US of the first lower pattern BP1.

In one example, the field insulating film 105 may entirely be on (e.g., may entirely cover or overlap) the sidewalls of the first lower pattern BP1. In some other embodiments, different from what is illustrated, the field insulating film 105 may be on (e.g., may cover or overlap) only portions of the sidewalls of the first lower pattern BP1. In this case, a portion of the first lower pattern BP1 may protrude in the third direction DR3 beyond the upper surface of the field insulating film 105.

Each of the first sheet patterns NS1 may be disposed higher than the upper surface of the field insulating film 105. The field insulating film 105 may include, for example, an oxide film, a nitride film, an oxynitride film, or a combination thereof. The field insulating film 105 is illustrated as being a single-layer film, but the present disclosure is not limited thereto.

The first gate structures GS1 may be disposed on the substrate 100. The first gate structures GS1 may extend in the second direction DR2. The first gate structures GS1 may be spaced apart in the first direction DR1. The first gate structures GS1 may be adjacent to each other in the first direction DR1. For example, the first gate structures GS1 may be disposed on both (i.e., opposing) sides of the first source/drain patterns 150 in the first direction DR1.

The first gate structures GS1 may be disposed on the first active pattern AP1. The first gate structures GS1 may intersect the first active pattern AP1.

The first gate structures GS1 may intersect the first lower pattern BP1. The first gate structures GS1 may surround each of the first sheet patterns NS1.

The first gate structures GS1 may include, for example, first gate electrodes 120 and a first gate insulating film 130.

Each of the first gate structures GS1 may include a plurality of first inner gate structures INT_GS1, which are disposed between adjacent first sheet patterns NS1 in the third direction DR3 and between the first lower pattern BP1 and the first sheet patterns NS1. The first inner gate structures INT_GS1 may be disposed between the upper surface BP1_US of the first lower pattern BP1 and the lower surfaces NS1_BS of the first sheet patterns NS1, and between the upper surfaces NS1_US and the respective lower surfaces NS1_BS of the first sheet patterns NS1, which face each other in the third direction DR3.

The number of first inner gate structures INT_GS1 may be proportional to the number of first sheet patterns NS1 included in the first active pattern AP1. For example, the number of first inner gate structures INT_GS1 may be the same as the number of first sheet patterns NS1. Since the first active pattern AP1 includes a plurality of first sheet patterns NS1, the first gate structures GS1 may include a plurality of first inner gate structures INT_GS1.

The first inner gate structures INT_GS1 may contact the upper surface BP1_US of the first lower pattern BP1, the upper surfaces NS1_US of the first sheet patterns NS1, and the lower surfaces NS1_BS of the first sheet patterns NS1. In the semiconductor device according to some embodiments, the first inner gate structures INT_GS1 may contact the first source/drain patterns 150, which will be described later. For example, the first inner gate structures INT_GS1 may directly contact the first source/drain patterns 150.

The first inner gate structures INT_GS1 include the first gate electrodes 120 and the first gate insulating film 130, which are disposed between adjacent first sheet patterns NS1 and between the first lower pattern BP1 and the first sheet patterns NS1.

In FIG. 2, which is a cross-sectional view taken along the first direction DR1, the width, in the first direction DR1, of the first inner gate structure INT_GS1 is illustrated as being uniform, but the present disclosure is not limited thereto. In some other embodiments, different from what is illustrated, the first inner gate structure INT_GS1 in contact with the upper surface BP1_US of the first lower pattern BP1 may have a largest width. For example, the width of the first inner gate structures INT_GS1 may be measured at the midpoint between the upper surfaces NS1_US and the respective lower surfaces NS1_BS of the first sheet patterns NS1, which face each other in the third direction DR3.

The first gate electrodes 120 may be disposed on the first lower pattern BP1. The first gate electrodes 120 may intersect the first lower pattern BP1. The first gate electrodes 120 may surround the first sheet patterns NS1.

Portions of the first gate electrodes 120 may be disposed between the adjacent first sheet patterns NS1 in the third direction DR3. When the first sheet patterns NS1 include a first lower sheet pattern and a first upper sheet pattern that are adjacent in the third direction DR3, portions of the first gate electrodes 120 may be disposed between the upper surfaces NS1_US of the first lower sheet patterns NS1 and the respective lower surfaces NS1_BS of the first upper sheet patterns NS1, which face each other. Additionally, portions of the first gate electrodes 120 may be disposed between the upper surface BP1_US of the first lower pattern BP1 and the lower surfaces NS1_BS of a lowermost first sheet pattern NS1 among the first sheet patterns NS1.

The first gate electrodes 120 may include at least one of a metal, a metal alloy, a conductive metal nitride, a metal silicide, a doped semiconductor material, a conductive metal oxide, or a conductive metal oxynitride. The first gate electrodes 120 may include, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), Al, copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or a combination thereof, but the present disclosure is not limited thereto. Here, the conductive metal oxide and conductive metal oxynitride may include oxidized forms of the aforementioned materials, but the present disclosure is not limited thereto.

The first gate electrodes 120 may be disposed on both sides of the first source/drain patterns 150, which will be described later. The first gate structures GS1 may be disposed on both sides of the first source/drain patterns 150 in the first direction DR1.

In one example, first gate electrodes 120 disposed on both sides of the first source/drain patterns 150 may be normal gate electrodes used as the gates of transistors. In another example, first gate electrodes 120 disposed on the first sides of the first source/drain patterns 150 may be used as the gates of transistors, but first gate electrodes 120 disposed on the second sides of the first source/drain patterns 150 may be dummy gate electrodes.

The first gate insulating film 130 may extend along the upper surface of the field insulating film 105 and the upper surface BP1_US of the first lower pattern BP1. The first gate insulating film 130 may surround the first sheet patterns NS1. The first gate insulating film 130 may be disposed around the circumferences of the first sheet patterns NS1. The first gate electrodes 120 may be disposed on the first gate insulating film 130. The first gate insulating film 130 may be disposed between the first gate electrodes 120 and the first sheet patterns NS1. Portions of the first gate insulating film 130 may be disposed between the adjacent first sheet patterns NS1 in the third direction DR3 and between the first lower pattern BP1 and the first sheet patterns NS1.

The first gate insulating film 130 may include silicon oxide, silicon-germanium oxide, germanium oxide, silicon oxynitride, silicon nitride, or a high-k dielectric material with a dielectric constant greater than that of silicon oxide. The high-k dielectric material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The first gate insulating film 130 is illustrated as being a single-layer film, but the present disclosure is not limited thereto. The first gate insulating film 130 may be a multilayer film. The first gate insulating film 130 may include an interfacial layer disposed between the first sheet patterns NS1 and the first gate electrodes 120, and a high-k dielectric insulating film.

The semiconductor device according to some embodiments may include a negative capacitance (NC) FET utilizing a negative capacitor. For example, the first gate insulating film 130 may include a ferroelectric material film with ferroelectric properties and a paraelectric material film with paraelectric properties.

The ferroelectric material film may have an NC, and the paraelectric material film may have positive capacitance (PC). For example, if two or more capacitors are connected in series, and each of the capacitors has a positive capacitance, the total capacitance of the capacitors is reduced compared to the capacitance of each of the capacitors. Conversely, if at least one of the capacitors has an NC, the total capacitance of the capacitors may have a positive value and may be greater than the absolute value of the capacitance of each of the capacitors.

When a ferroelectric material film with an NC and a paraelectric material film with a PC are connected in series, the total capacitance of the ferroelectric and paraelectric material films may increase. Utilizing this capacitance increase, the transistor including the ferroelectric material film can have a subthreshold swing (SS) of 60 mV/decade or less at room temperature.

The ferroelectric material film may have ferroelectric properties. For example, the ferroelectric material film may include at least one of hafnium oxide, hafnium zirconium oxide, barium strontium titanium oxide, barium titanium oxide, and/or lead zirconium titanium oxide.

Here, the hafnium zirconium oxide may be, for example, a material obtained by doping hafnium oxide with zirconium (Zr). In some other embodiments, the hafnium zirconium oxide may be the compound of hafnium (Hf), Zr, and oxygen (O).

The ferroelectric material film may further include a dopant. For example, the dopant may include at least one of Al, Ti, Nb, lanthanum (La), yttrium (Y), magnesium (Mg), Si, calcium (Ca), cerium (Ce), dysprosium (Dy), erbium (Er), gadolinium (Gd), Ge, scandium (Sc), strontium (Sr), and/or Sn. The type of the dopant included in the ferroelectric material film may vary depending on the type of the ferroelectric material included in the ferroelectric material film.

When the ferroelectric material film includes hafnium oxide, the dopant included in the ferroelectric material film may include at least one of Gd, Si, Zr, Al, and/or Y.

If the dopant is Al, the ferroelectric material film may include 3 to 8 atomic % (at %) of Al. Here, the proportion of the dopant may be the ratio of Al to the sum of Hf and Al.

If the dopant is Si, the ferroelectric material film may include 2 to 10 at % of Si. If the dopant is Y, the ferroelectric material film may include 2 to 10 at % of Y. If the dopant is Gd, the ferroelectric material film may include 1 to 7 at % of Gd. If the dopant is Zr, the ferroelectric material film may include 50 to 80 at % of Zr.

The paraelectric material film may have paraelectric properties. For example, the paraelectric material film may include at least one of silicon oxide and a high-k metal oxide. The high-k metal oxide may include at least one of hafnium oxide, zirconium oxide, and/or aluminum oxide, but the present disclosure is not limited thereto.

The ferroelectric material film and the paraelectric material film may include the same material. The ferroelectric material film may have ferroelectric properties, but the paraelectric material film may not have ferroelectric properties. For example, if both the ferroelectric and paraelectric material films include hafnium oxide, the crystal structure of the hafnium oxide in the ferroelectric material film may differ from the crystal structure of the hafnium oxide in the paraelectric material film.

The ferroelectric material film may have a thickness that exhibits ferroelectric properties. For example, the thickness of the ferroelectric material film may be 0.5 to 10 nm, but the present disclosure is not limited thereto. Since the critical thickness for exhibiting ferroelectric properties may vary from one ferroelectric material to another, the thickness of the ferroelectric material film may vary depending on its material.

For example, the first gate insulating film 130 may include one ferroelectric material film. In some other embodiments, the first gate insulating film 130 may include a plurality of ferroelectric material films that are spaced apart from one another. The first gate insulating film 130 may have a layered film structure in which a plurality of ferroelectric material films and a plurality of paraelectric material films are alternately stacked.

First gate spacers 140 may be disposed on the sidewalls of the first gate electrodes 120.

The first gate spacers 140 may not be disposed between the first lower pattern BP1 and the first sheet patterns NS1, or between the adjacent first sheet patterns NS1 in the third direction DR3.

The first gate spacers 140 may include, for example, at least one of silicon nitride, silicon oxynitride, silicon oxide, silicon oxycarbonitride, silicon boron nitride, silicon oxyboron nitride, silicon oxycarbide, or a combination thereof. The first gate spacers 140 are illustrated as being single-layer films, but the present disclosure is not limited thereto.

First gate capping patterns 145 may be disposed on the first gate electrodes 120 and the first gate spacers 140. The upper surfaces of the first gate capping patterns 145 may be on the same plane as the upper surface of the first interlayer insulating film 190. In some other embodiments, different from what is illustrated, the first gate capping patterns 145 may be disposed between the first gate spacers 140.

The first gate capping patterns 145 may include, for example, at least one of silicon nitride, silicon oxynitride, silicon carbonitride, silicon oxycarbonitride, or a combination thereof. The first gate capping patterns 145 may include a material with an etch selectivity with respect to the interlayer insulating film 190.

The first source/drain patterns 150 may be disposed on the first active pattern AP1. The first source/drain patterns 150 may be disposed on the first lower pattern BP1. The first source/drain patterns 150 may be connected to the first sheet patterns NS1. The first source/drain patterns 150 may contact the first sheet patterns NS1.

The first source/drain patterns 150 may be disposed on the sides of the first gate structures GS1. The first source/drain patterns 150 may be disposed between adjacent first gate structures GS1 in the first direction DR1. For example, the first source/drain patterns 150 may be disposed on both sides of the first gate structures GS1. In some other embodiments, different from what is illustrated, the first source/drain patterns 150 may be disposed on the first sides, but not on the second sides, of the first gate structures GS1.

The first source/drain patterns 150 may be included in the sources/drains of transistors using the first sheet patterns NS1 as channel regions.

The first source/drain patterns 150 may be disposed within first source/drain recesses 150R. The first source/drain patterns 150 may fill the first source/drain recesses 150R.

The first source/drain recesses 150R may extend in the third direction DR3. The first source/drain recesses 150R may be defined between adjacent first gate structures GS1 in the first direction DR1.

The lower surfaces of the first source/drain recesses 150R may be defined by the first lower pattern BP1. For example, the sidewalls of the first source/drain recesses 150R may be defined by the first sheet patterns NS1 and the first inner gate structures INT_GS1.

The first inner gate structures INT_GS1 may include upper surfaces facing the lower surfaces NS1_BS of the first sheet patterns NS1. The first inner gate structures INT_GS1 may include lower surfaces facing the upper surfaces NS1_US of the first sheet patterns NS1 or the upper surface BP1_US of the first lower pattern BP1. The first inner gate structures INT_GS1 may include sidewalls connecting the upper surfaces and the lower surfaces of the first inner gate structures INT_GS1. For example, the sidewalls of the first inner gate structures INT_GS1 may define portions of the sidewalls of the first source/drain recesses 150R.

Between the lowermost first sheet pattern NS1 and the first lower pattern BP1, the boundary between the first gate insulating film 130 and the first lower pattern BP1 may correspond to the upper surface BP1_US of the first lower pattern BP1. The lower surfaces of the first source/drain recesses 150R may be lower than the upper surface BP1_US of the first lower pattern BP1.

The sidewalls of the first source/drain recesses 150R may have a wavy shape. The first source/drain recesses 150R may include a plurality of first width expansion regions 150R_ER.

The first width expansion regions 150R_ER may be defined above the upper surface BP1_US of the first lower pattern BP1.

The first width expansion regions 150R_ER may be defined between the adjacent first sheet patterns NS1 in the third direction DR3. The first width expansion regions 150R_ER may be defined between the first lower pattern BP1 and the first sheet patterns NS1. The first width expansion regions 150R_ER may extend between the adjacent first sheet patterns NS1 in the third direction DR3. The first width expansion regions 150R_ER may be defined between adjacent first inner gate structures INT_GS1 in the first direction DR1.

The first width expansion regions 150R_ER include portions whose width in the first direction DR1 increases away from the upper surface BP1_US of the first lower pattern BP1 and portions whose width in the first direction DR1 decreases away from the upper surface BP1_US of the first lower pattern BP1. For example, the width of the first width expansion regions 150R_ER may increase and then decrease away from the upper surface BP1_US of the first lower pattern BP1.

The first width expansion regions 150R_ER have a greatest width between the first sheet patterns NS1 and the first lower pattern BP1 or between the adjacent first sheet patterns NS1 in the third direction DR3.

The first source/drain patterns 150 may contact the first lower pattern BP1. The first gate insulating film 130 of the first inner gate structures INT_GS1 may contact the first source/drain patterns 150.

The first source/drain patterns 150 may include a first semiconductor material film 151, a second semiconductor material film 152, and a third semiconductor material film 153.

The first semiconductor material film 151 may extend along the sidewalls and lower surfaces of the first source/drain recesses 150R. The first semiconductor material film 151 may include sidewall portions 151S and bottom portions 151B. The sidewall portions 151S of the first semiconductor material film 151 may extend along the sidewalls of the first source/drain recesses 150R. The bottom portions 151B of the first semiconductor material film 151 may extend along the lower surfaces of the first source/drain recesses 150R.

For example, the first semiconductor material film 151 may be continuously formed along the first source/drain recesses 150R. Portions of the first semiconductor material film 151 that are formed along first source/drain recesses 150R defined by the first sheet patterns NS1 may be directly connected to portions of the first semiconductor material film 151 that are formed along first source/drain recesses 150R defined by the first inner gate structures INT_GS1. The sidewall portions 151S of the first semiconductor material film 151 may be directly connected to the bottom portions 151B of the first semiconductor material film 151.

For example, the first semiconductor material film 151 may contact the first sheet patterns NS1, the first lower pattern BP1, and the first inner gate structures INT_GS1. The first semiconductor material film 151 may contact the first gate insulating film 130 of the first inner gate structures INT_GS1.

The first semiconductor material film 151 may include an outer side surface and an inner side surface. The outer surface of the first semiconductor material film 151 may contact the first sheet patterns NS1 and the first lower pattern BP1. For example, the outer side surface of the first semiconductor material film 151 may contact the sidewalls of the first inner gate structures INT_GS1.

The inner side surface of the first semiconductor material film 151 may be opposite to the outer side surface of the first semiconductor material film 151. The inner side surface of the first semiconductor material film 151 may face the second and third semiconductor material films 152 and 153.

The second semiconductor material film 152 may be disposed on the first semiconductor material film 151. The second semiconductor material film 152 may fill portions of the first source/drain recesses 150R.

The third semiconductor material film 153 may be disposed on the second semiconductor material film 152. The second and third semiconductor material films 152 and 153 may be disposed on the first semiconductor material film 151. The second semiconductor material film 152 may be disposed between the first and third semiconductor material films 151 and 153.

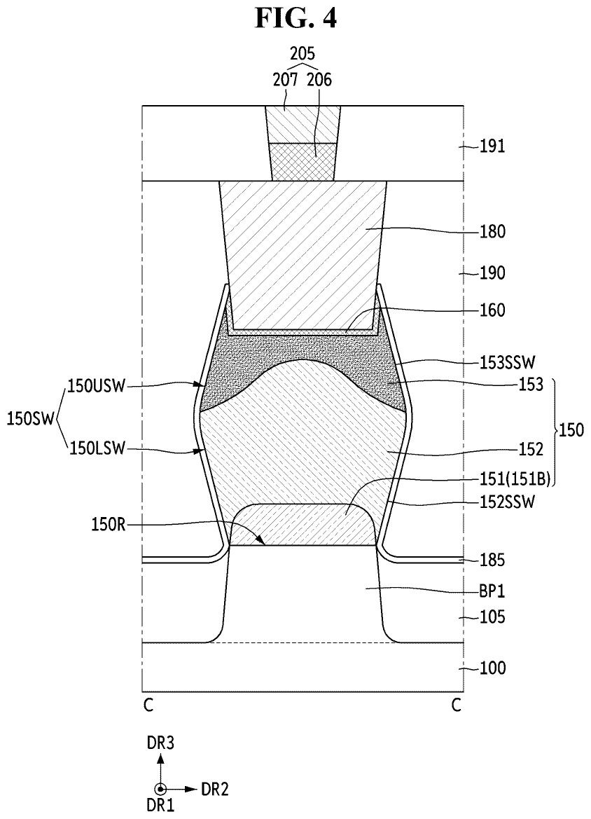

In a cross-sectional view taken along the second direction DR2, such as FIG. 4, the first source/drain patterns 150 may include sidewalls 150SW extending in the third direction DR3.

The sidewalls 150SW of the first source/drain patterns 150 may include lower sidewalls 150LSW and upper sidewalls 150USW. The lower sidewalls 150LSW and the upper sidewalls 150USW of the first source/drain patterns 150 may be sloped surfaces inclined with respect to the third direction DR3.

The lower sidewalls 150LSW of the first source/drain patterns 150 may be closer than the upper sidewalls 150USW of the first source/drain patterns 150 to the field insulating film 105.

The distance between the lower sidewalls 150LSW of the first source/drain patterns 150 may increase away from the first lower pattern BP1. The distance between the upper sidewalls 150USW of the first source/drain patterns 150 may decrease away from the first lower pattern BP1.

In a cross-sectional view taken along the second direction DR2, such as FIG. 4, the second semiconductor material film 152 may include sidewalls 152SW extending in the third direction DR3. The third semiconductor material film 153 may include sidewalls 153SW extending in the third direction DR3. The sidewalls 152SW of the second semiconductor material film 152 and the sidewalls 153SW of the third semiconductor material film 153 may both include sloped surfaces inclined with respect to the third direction DR3.

In the semiconductor device according to some embodiments, the sidewalls 150SW of the first source/drain patterns 150 may be defined by the second and third semiconductor material films 152 and 153. The sidewalls 150SW of the first source/drain patterns 150 may include the sidewalls 152SW of the second semiconductor material film 152 and the sidewalls 153SW of the third semiconductor material film 153.

The first semiconductor material film 151 may have a monocrystalline structure. The first semiconductor material film 151 may be in a monocrystalline phase.

In the semiconductor device according to some embodiments, the second semiconductor material film 152 may have a polycrystalline structure, and the third semiconductor material film 153 may have an amorphous structure. The second semiconductor material film 152 may be in a polycrystalline phase, and the third semiconductor material film 153 may be in an amorphous phase. The second semiconductor material film 152 with a polycrystalline structure may be disposed between the first semiconductor material film 151 with a monocrystalline structure and the third semiconductor material film 153 with an amorphous structure.

The first source/drain patterns 150 may include, for example, an elemental semiconductor material such as Si or Ge. Additionally, the first source/drain patterns 150 may include a binary or ternary compound including at least two of C, Si, Ge, and Sn, or a compound obtained by doping the binary or ternary compound with a Group IV element.

In one example, the first source/drain patterns 150 may include an n-type impurity element. The n-type impurity element may include, for example, at least one of P, As, Sb, or bismuth (Bi), but the present disclosure is not limited thereto.

First source/drain patterns 150 doped with the n-type impurity element may be included in the sources/drains of NMOS transistors. In the first source/drain patterns 150 included in the sources/drains of NMOS transistors, the first, second, and third semiconductor material films 151, 152, and 153 may each include Si. The n-type impurity element doped in the first semiconductor material film 151 may be different from the n-type impurity element doped in the second semiconductor material film 152, but the present disclosure is not limited thereto.

In another example, the first source/drain patterns 150 may include a p-type impurity element. The p-type impurity element may include at least one of boron (B) or gallium (Ga), but the present disclosure is not limited thereto.

First source/drain patterns 150 doped with the p-type impurity element may be included in the sources/drains of PMOS transistors. In the first source/drain patterns 150 included in the sources/drains of PMOS transistors, the first, second, and third semiconductor material films 151, 152, and 153 may each include SiGe. The Ge content in the first semiconductor material film 151 may be lower than the Ge content in the second semiconductor material film 152. The Ge content in the first semiconductor material film 151 may also be lower than the Ge content in the third semiconductor material film 153.

Portions of the first semiconductor material film 151 that contact the first sheet patterns NS1 used as channel regions may have a monocrystalline structure. In this manner, the degradation of the performance of the semiconductor device according to some embodiments can be prevented.

Meanwhile, the concentration (/cm³) of impurity elements that can be doped into semiconductor patterns with a monocrystalline structure is lower than the concentration of impurity elements that can be doped into semiconductor patterns with an amorphous structure.

When the third semiconductor material film 153 has an amorphous structure instead of a monocrystalline structure, the concentration of impurity elements doped into the third semiconductor material film 153 may increase. In other words, as more impurity elements are doped into the third semiconductor material film 153, the resistance of the first source/drain patterns 150 may decrease. Additionally, as the concentration of impurity elements doped into the third semiconductor material film 153 increases, the contact resistance between the first source/drain patterns 150 and the first source/drain contacts 180 may also decrease.

Accordingly, the performance and reliability of the semiconductor device according to some embodiments can be improved.

The source/drain etch stop film 185 may extend along the outer sidewalls of the first gate spacers 140 and the profile of the first source/drain patterns 150. The source/drain etch stop film 185 may extend along the sidewalls 150SW of the first source/drain patterns 150. The source/drain etch stop film 185 may extend along the upper surface of the field insulating film 105.

In a cross-sectional view such as FIG. 2, the first gate capping patterns 145 may be disposed on the upper surface of the source/drain etch stop film 185. In some other embodiments, different from what is illustrated, the source/drain etch stop film 185 may extend along the sidewalls of the first gate capping patterns 145.

The source/drain etch stop film 185 may include a material with an etch selectivity with respect to the first interlayer insulating film 190, which will be described later. The source/drain etch stop film 185 may include, for example, at least one of silicon nitride, silicon oxynitride, silicon oxycarbonitride, silicon boron nitride, silicon oxyboron nitride, silicon oxycarbide, or a combination thereof, but the present disclosure is not limited thereto.

The first interlayer insulating film 190 may be disposed on the source/drain etch stop film 185. The first interlayer insulating film 190 may be disposed on the first source/drain patterns 150. The first interlayer insulating film 190 may not be on (e.g., may not cover or overlap) the upper surfaces of the first gate capping patterns 145. For example, the upper surface of the first interlayer insulating film 190 may be on the same plane as the upper surfaces of the first gate capping patterns 145.

The first interlayer insulating film 190 may include, for example, at least one of silicon oxide, silicon nitride, silicon oxynitride, and a low-k material. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoam such as polypropylene oxide, Carbon Doped silicon Oxide (CDO), Organo Silicate Glass (OSG), SiLK, Amorphous Fluorinated Carbon, silica aerogel, silica xerogel, mesoporous silica, or a combination thereof, but the present disclosure is not limited thereto.

The first source/drain contacts 180 may be disposed on the first source/drain patterns 150. The first source/drain contacts 180 may be connected to the first source/drain patterns 150.

The first source/drain contacts 180 may be connected to the first source/drain patterns 150, penetrating the first interlayer insulating film 190 and the source/drain etch stop film 185.

Portions of the first source/drain contacts 180 may be disposed within the third semiconductor material film 153.

The width, in the first direction DR1, of the first source/drain contacts 180 may increase away from the first lower pattern BP1. From a cross-sectional perspective, portions of the first interlayer insulating film 190 may be disposed on the sidewalls of the first source/drain contacts 180 and the sidewalls of the first gate structures GS1.

The first source/drain contacts 180 are illustrated as being single-layer films, but the present disclosure is not limited thereto. In some other embodiments, the first source/drain contacts 180 may have a multilayer structure including a contact plug film and a contact barrier film.

The first source/drain contacts 180 may include, for example, at least one of a metal, a conductive metal nitride, a conductive metal carbide, a conductive metal oxide, a conductive metal carbonitride, and/or a two-dimensional (2D) material. The 2D material may be a metallic material and/or a semiconductor material. The 2D material may include a 2D allotrope or compound, for example, at least one of graphene, molybdenum disulfide (MoS₂), molybdenum diselenide (MoSe₂), tungsten selenide (WSe₂), and/or tantalum disulfide (WS₂), but the present disclosure is not limited thereto. That is, these 2D materials are merely example, and thus, the present disclosure is not limited thereto.

A first contact silicide film 160 may be further disposed between the first source/drain contacts 180 and the first source/drain patterns 150. The first contact silicide film 160 may include a metal silicide material.

A second interlayer insulating film 191 may be disposed on the first interlayer insulating film 190. The second interlayer insulating film 191 may include, for example, at least one of silicon oxide, silicon nitride, silicon oxynitride, and/or a low-k material.

A wiring structure 205 may be disposed within the second interlayer insulating film 191. The wiring structure 205 may be connected to the first source/drain contacts 180. The wiring structure 205 may include wiring lines and wiring vias 206.

The wiring lines 207 and the wiring vias 206 are illustrated as being distinct from each other, but the present disclosure is not limited thereto. That is, for example, the wiring vias 206 may be formed, and the wiring lines 207 may be formed. In another example, the wiring vias 206 and the wiring lines 207 may be formed at the same time.

The wiring lines 207 and the wiring vias 206 are illustrated as being single films, but the present disclosure is not limited thereto. The wiring lines 207 and the wiring vias 206 may include, for example, at least one of a metal, a conductive metal nitride, a conductive metal carbide, a conductive metal oxide, a conductive metal carbonitride, and/or a 2D material.

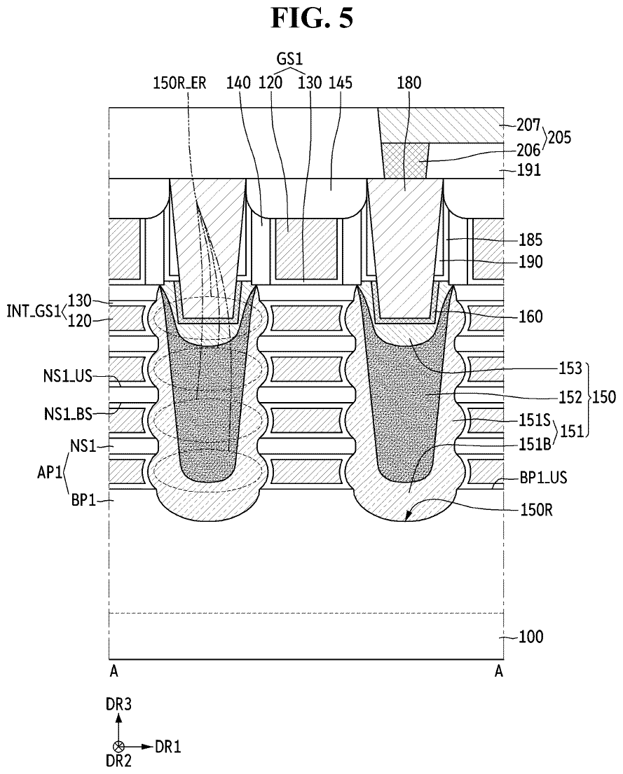

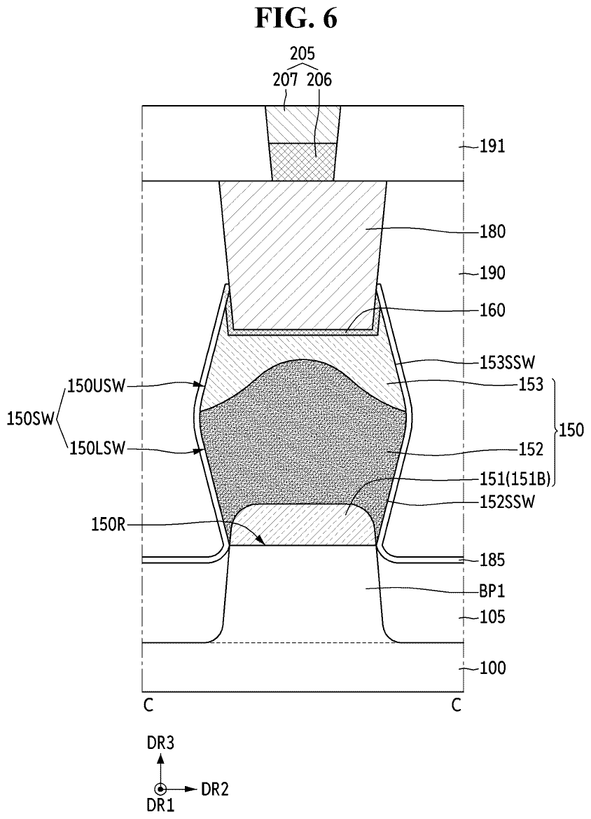

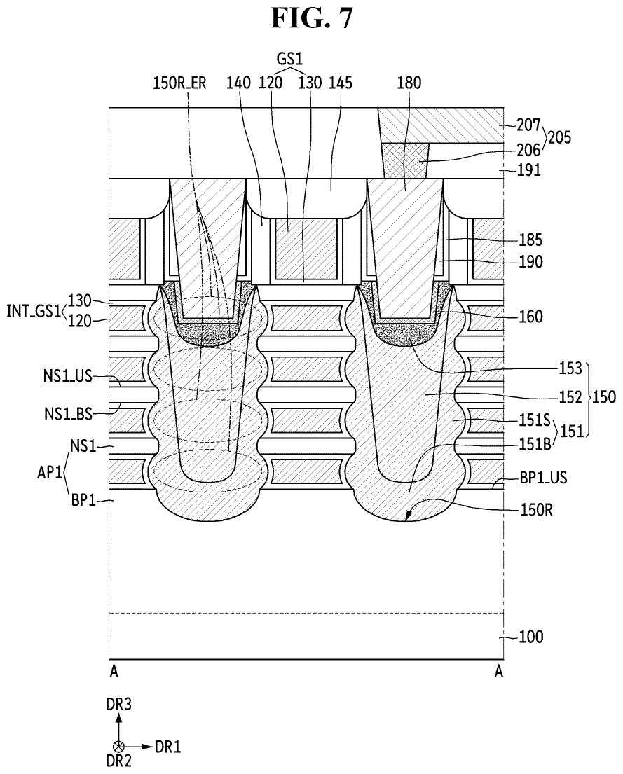

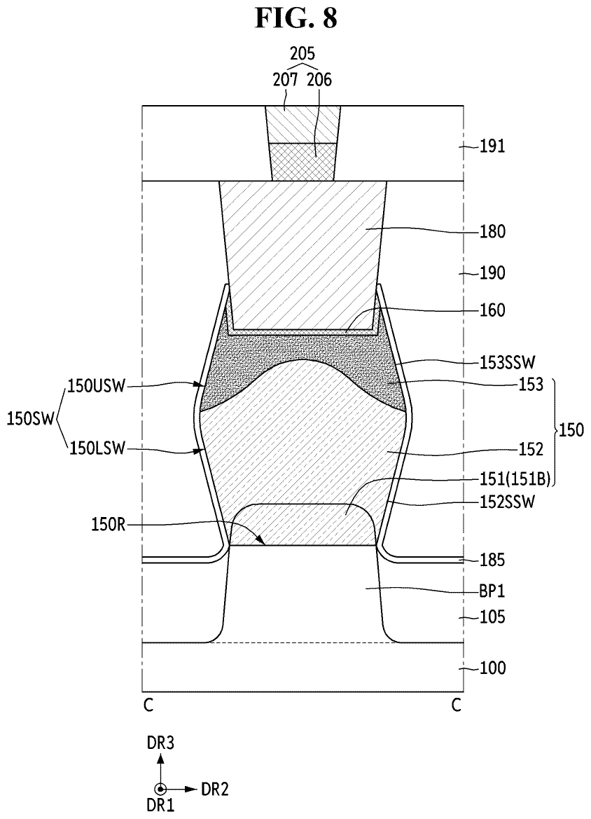

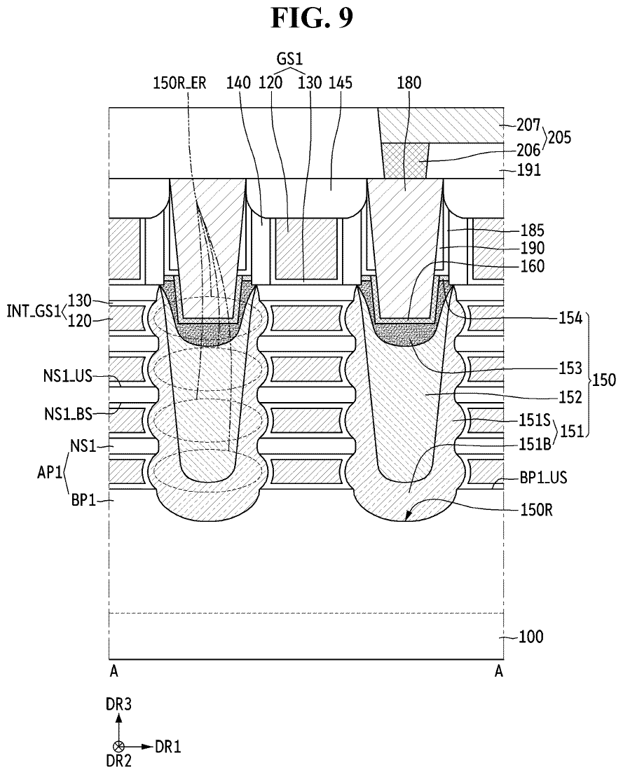

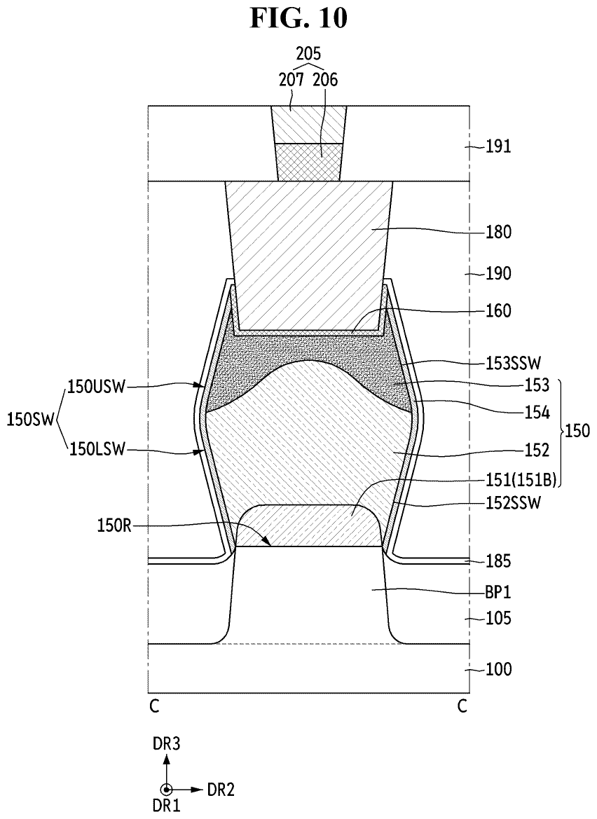

FIGS. 5 and 6 are diagrams illustrating a semiconductor device according to some embodiments. FIGS. 7 and 8 are diagrams illustrating a semiconductor device according to some embodiments. FIGS. 9 and 10 are diagrams illustrating a semiconductor device according to some embodiments. For convenience, the embodiments of FIGS. 5 through 10 will hereinafter be described, focusing mainly on the differences from the embodiments of FIGS. 1 through 4.

Referring to FIGS. 5 and 6, in the semiconductor device according to some embodiments, a second semiconductor material film 152 may have an amorphous structure, and a third semiconductor material film 153 may have a polycrystalline structure.

The second semiconductor material film 152 may be in an amorphous phase, and the third semiconductor material film 153 may be in a polycrystalline phase. The second semiconductor material film 152 with an amorphous structure may be disposed between a first semiconductor material film 151 with a monocrystalline structure and the third semiconductor material film 153 with a polycrystalline structure.

Referring to FIGS. 7 and 8, in the semiconductor device according to some embodiments, a second semiconductor material film 152 may have a monocrystalline structure.

A first semiconductor material film 151 and the second semiconductor material film 152 may both have a monocrystalline phase.

Referring to FIGS. 9 and 10, in the semiconductor device according to some embodiments, first source/drain patterns 150 may further include a fourth semiconductor material film 154.

The fourth semiconductor material film 154 may be disposed on a second semiconductor material film 152 and a third semiconductor material film 153. The fourth semiconductor material film 154 may extend along sidewalls 152SW of the second semiconductor material film 152 and sidewalls 153SW of the third semiconductor material film 153. For example, the fourth semiconductor material film 154 may contact the sidewalls 152SW of the second semiconductor material film 152 and the sidewalls 153SW of the third semiconductor material film 153.

Sidewalls 150SW of the first source/drain patterns 150 may be defined by the fourth semiconductor material film 154. The fourth semiconductor material film 154 may include lower sidewalls 150LSW and upper sidewalls 150USW of the first source/drain patterns 150.

The fourth semiconductor material film 154 may include a semiconductor material. For example, the fourth semiconductor material film 154 may have a polycrystalline structure. In another example, the fourth semiconductor material film 154 may have an amorphous structure.

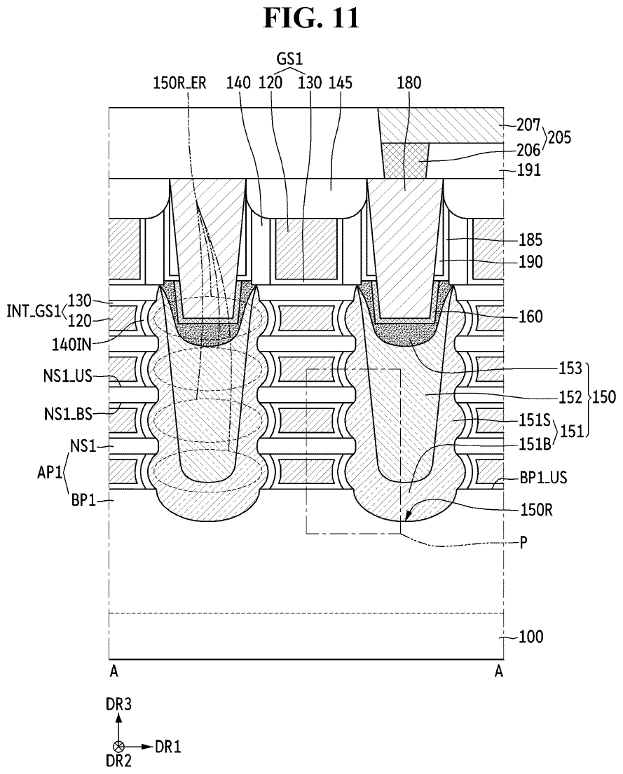

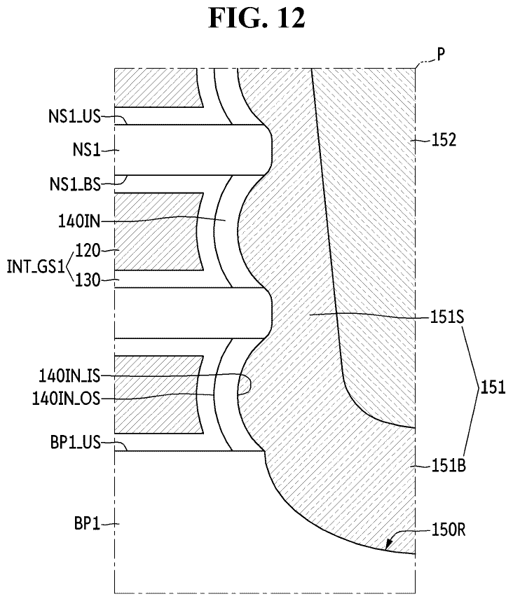

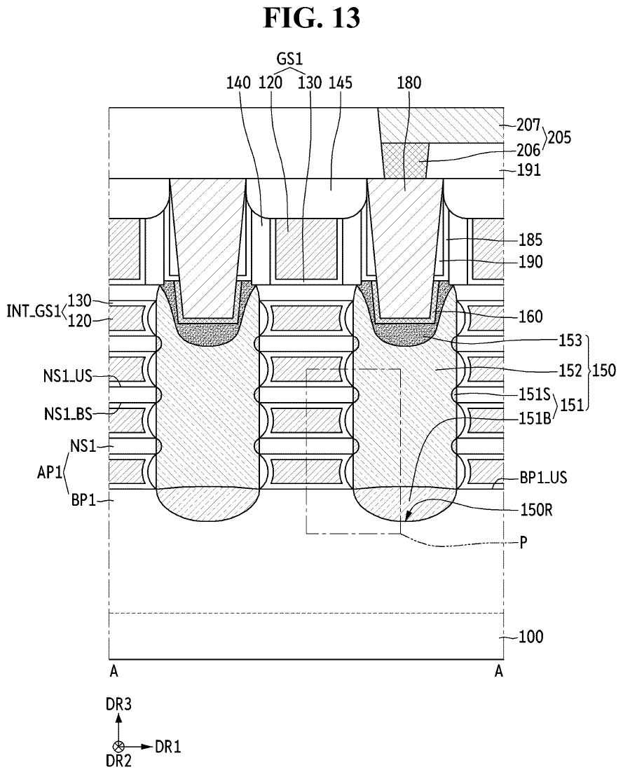

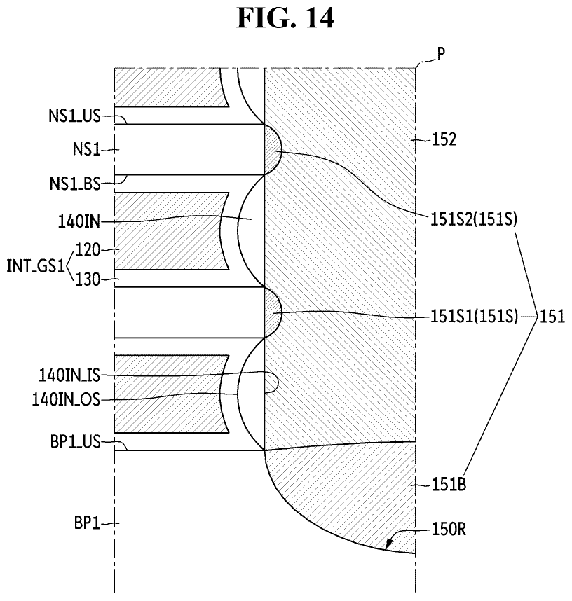

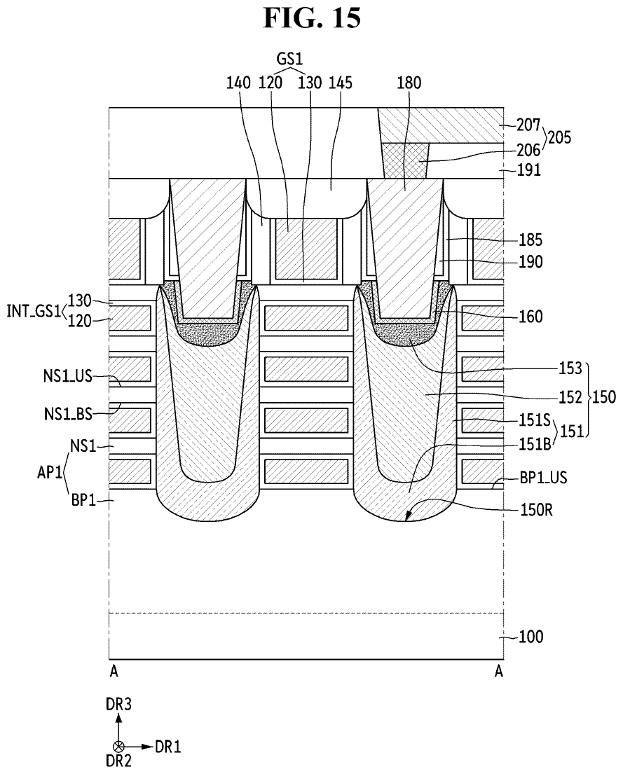

FIGS. 11 and 12 are diagrams illustrating a semiconductor device according to some embodiments. FIGS. 13 and 14 are diagrams illustrating a semiconductor device according to some embodiments. FIG. 15 is a diagram illustrating a semiconductor device according to some embodiments. For convenience, the embodiments of FIGS. 5 through 10 will hereinafter be described, focusing mainly on the differences from the embodiments of FIGS. 1 through 4.

For reference, FIGS. 12 and 14 are enlarged views of parts P of FIGS. 11 and 13, respectively.

Referring to FIGS. 11 through 14, the semiconductor devices according to some embodiments may further include inner spacers 140IN disposed between first inner gate structures INT_GS1 and first source/drain patterns 150.

The inner spacers 140IN may be disposed between adjacent first sheet patterns NS1 in a third direction DR3, and between a first lower pattern BP1 and the first sheet patterns NS1. The inner spacers 140IN may contact the first lower pattern BP1 and the first sheet patterns NS1.

The inner spacers 140IN may contact first gate structures GS1. For example, the inner spacers 140IN may contact the first inner gate structures INT_GS1. The inner spacers 140IN may contact a first gate insulating film 130 included in the first inner gate structures INT_GS1. The first inner gate structures INT_GS1 may not contact the first source/drain patterns 150.

The inner spacers 140IN may include inner sidewalls 140IN_IS and outer sidewalls 140IN_OS that are opposite to the respective inner sidewalls 140IN_IS in a first direction DR1. The outer sidewalls 140IN_OS of the inner spacers 140 may face the first inner gate structures INT_GS1. The first inner gate structures INT_GS1 may contact the outer sidewalls 140IN_OS of the inner spacers 140IN. The inner sidewalls 140IN_IS of the inner spacers 140IN may face the first source/drain patterns 150.

The sidewalls of first source/drain recesses 150R may be defined by the first sheet patterns NS1 and the inner spacers 140IN. The sidewalls of the first source/drain recesses 150R may include the inner sidewalls 140IN_IS of the inner spacers 140IN.

The inner spacers 140IN may include, for example, at least one of silicon nitride, silicon oxynitride, silicon oxide, silicon oxycarbonitride, silicon boron nitride, silicon oxyboron nitride, silicon oxycarbide, or a combination thereof.

In FIGS. 11 and 12, sidewall portions 151S of a first semiconductor material film 151 may be continuously formed along the first source/drain recesses 150R. The first semiconductor material film 151 may extend along the inner sidewalls 140IN_IS of the inner spacers 140IN.

Portions of the first semiconductor material film 151 that are formed along first source/drain recesses 150R defined by the first sheet patterns NS1 may be directly connected to portions of the first semiconductor material film 151 that are formed along first source/drain recesses 150R defined by the inner spacers 140IN.

In FIGS. 13 and 14, first source/drain recesses 150R may not include multiple first width expansion regions 150R_ER. Sidewall portions 151S of a first semiconductor material film 151 may include multiple sub-semiconductor patterns (151S1 and 151S2). For example, the sidewall portions 151S of the first semiconductor material film 151 may include first sub-semiconductor patterns 151S1 and second sub-semiconductor patterns 151S2 spaced apart in a third direction DR3. For example, the first sub-semiconductor patterns 151S1 may be the sub-semiconductor patterns closest to a first lower pattern BP1. The first sub-semiconductor patterns 151S1 and the second sub-semiconductor patterns 151S2 may not be directly connected. The first sub-semiconductor patterns 151S1 and the second sub-semiconductor patterns 151S2 may be connected via a second semiconductor material film 152.

The first sub-semiconductor patterns 151S1 and the second sub-semiconductor patterns 151S2 may not be directly connected to bottom portions 151B of the first semiconductor material film 151. In other words, the sidewall portions 151S of the first semiconductor material film 151 may not contact the bottom portions 151B of the first semiconductor material film 151. Inner spacers 140IN may be disposed between the sidewall portions 151S and the bottom portions 151B of the first semiconductor material film 151, and between adjacent sidewall portions 151S of the first semiconductor material film 151 in the third direction DR3. The inner spacers 140IN may be disposed between the first sub-semiconductor patterns 151S1 and the second sub-semiconductor patterns 151S2, and between the first sub-semiconductor patterns 151S1 and the bottom portions 151B of the first semiconductor material film 151.

Referring to FIG. 15, in the semiconductor device according to some embodiments, first source/drain recesses 150R may not include multiple first width expansion regions (“150R_ER” in FIG. 2).

The sidewalls of the first source/drain recesses 150R may not have a wavy shape. The upper portions of the sidewalls of the first source/drain recesses 150R may narrow in a first direction DR1 away from a first lower pattern BP1 (e.g., in a third direction DR3). In other words, sidewall portions 151S of the first semiconductor material film 151 may narrow in a first direction DR1 away from a first lower pattern BP1 in a third direction DR3.

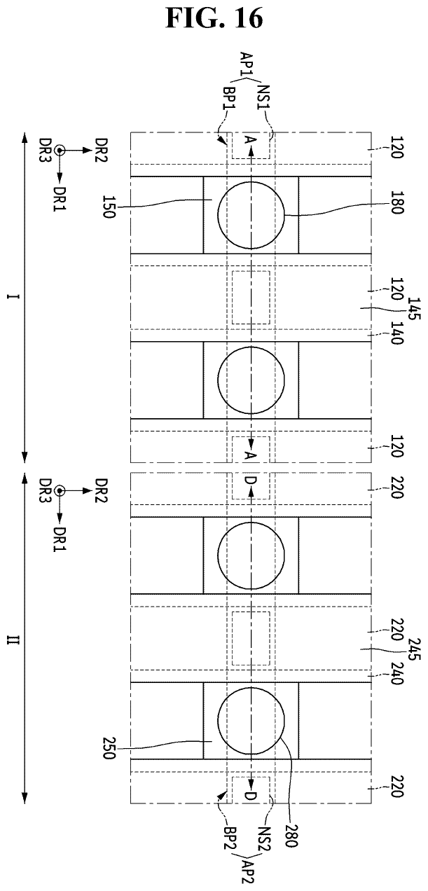

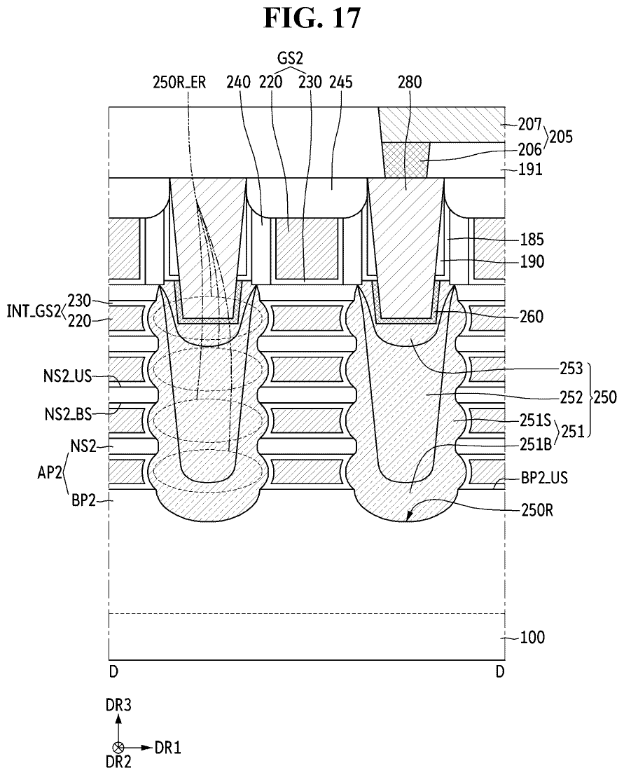

FIG. 16 is an example plan view illustrating a semiconductor device according to some embodiments. FIG. 17 is a cross-sectional view taken along line D-D of FIG. 16.

For reference, a cross-sectional view taken along line A-A of FIG. 16 is substantially the same as FIGS. 2, 5, 7, 9, 11, 13, and 15, and thus, any redundant details thereof will be briefly described or omitted. In other words, the following description will mainly focus on a second region II of FIG. 16.

Referring to FIGS. 16 and 17, the semiconductor device according to some embodiments may include a first active pattern AP1, a plurality of first gate structures GS1, first source/drain patterns 150, a second active pattern AP2, a plurality of second gate structures GS2, and second source/drain patterns 250.

A substrate 100 may include a first region I and the second region II. For example, the first region I may be an NMOS formation region, and the second region II may be a PMOS formation region.

The first active pattern AP1, the first gate structures GS1, and the first source/drain patterns 150 may be disposed in the first region I of the substrate 100. The second active pattern AP2, the second gate structures GS2, and the second source/drain patterns 250 may be disposed in the second region II of the substrate 100.

The second active pattern AP2 may include a second lower pattern BP2 and a plurality of second sheet patterns NS2. The second sheet patterns NS2 may be disposed on an upper surface BP2_US of the second lower pattern BP2. The second sheet patterns NS2 include upper surfaces NS2_US and lower surfaces NS2_BS that are opposite to the respective upper surfaces NS2_US in a third direction DR3. The second lower pattern BP2 and the second sheet patterns NS2 may each include one of an elemental semiconductor material such as Si or Ge, a Group IV-IV compound semiconductor, or a Group III-V compound semiconductor. In some embodiments, the second lower pattern BP2 may be a Si lower pattern including Si, and the second sheet patterns NS2 may be Si sheet patterns including Si. An upper surface AP2_US of the second active pattern AP2 may correspond to the upper surface of an uppermost second sheet pattern NS2 among the second sheet patterns NS2.

The description of the second active pattern AP2 may be substantially the same as that of the first active pattern AP1.

The second gate structures GS2 may be disposed on the substrate 100. The second gate structures GS2 may be disposed on the second active pattern AP2. The second gate structures GS2 may intersect the second active pattern AP2. The second gate structures GS2 may intersect the second lower pattern BP2. The second gate structures GS2 may surround each of the second sheet patterns NS2. The second gate structures GS2 may include a plurality of second inner gate structures INT_GS2, which are disposed between adjacent second sheet patterns NS2 in the third direction DR3, and between the second lower pattern BP2 and the second sheet patterns NS2. The second gate structures GS2 may include, for example, second gate electrodes 220 and a second gate insulating film 230.

The description of the second gate structures GS2 may be substantially the same as that of the first gate structures GS1. The description of second gate spacers 240 and second gate capping patterns 245 may be substantially the same as that of first gate spacers 140 and first gate capping patterns 145.

The second source/drain patterns 250 may be disposed on the second active pattern AP2. The second source/drain patterns 250 may be disposed on the second lower pattern BP2. For example, the second source/drain patterns 250 may be disposed on both sides of the second gate structures GS2.

The second source/drain patterns 250 may be connected to the second sheet patterns NS2. The second source/drain patterns 250 may contact the second sheet patterns NS2. The second source/drain patterns 250 may be included in the sources/drains of transistors that use the second sheet patterns NS2 as channel regions.

The second source/drain patterns 250 may be disposed within second source/drain recesses 250R. The second source/drain recesses 250R may include a plurality of second width expansion regions 250R_ER. The lower surfaces of the second source/drain recesses 250R may be defined by the second lower pattern BP2. The sidewalls of the second source/drain recesses 250R may be defined by the second sheet patterns NS2 and the second inner gate structures INT_GS2.

The second source/drain patterns 250 may contact the second gate insulating film 230 of the second inner gate structures INT_GS2 and the second lower pattern BP2. In some other embodiments, different from what is illustrated, inner spacers, such as those described with reference to FIGS. 11 and 12, may be disposed between the second source/drain patterns 250 and the second inner gate structures INT_GS2.

The second source/drain patterns 250 may include a fifth semiconductor material film 251, a sixth semiconductor material film 252, and a seventh semiconductor material film 253.

The fifth semiconductor material film 251 may extend along the sidewalls and lower surfaces of the second source/drain recesses 250R. The fifth semiconductor material film 251 may include sidewall portions 251S and bottom portions 251B. The sidewall portions 251S of the fifth semiconductor material film 251 may extend along the sidewalls of the second source/drain recesses 250R. The bottom portions 251B of the fifth semiconductor material film 251 may extend along the lower surfaces of the second source/drain recesses 250R.

The fifth semiconductor material film 251 may be continuously formed along the second source/drain recesses 250R. The sidewall portions 251S of the fifth semiconductor material film 251 may be directly connected to the bottom portions 251B of the fifth semiconductor material film 251.

The sixth semiconductor material film 252 may be disposed on the fifth semiconductor material film 251. The seventh semiconductor material film 253 may be disposed on the sixth semiconductor material film 252. The sixth semiconductor material film 252 may be disposed between the fifth and seventh semiconductor material films 251 and 253.

For example, the fifth, sixth, and seventh semiconductor material films 251, 252, and 253 may all have a monocrystalline structure. In other words, the second source/drain patterns 250 may have a monocrystalline structure.

The second source/drain patterns 250 may include a doped p-type impurity element. The first source/drain patterns 150 may include a doped n-type impurity element.

Second source/drain contacts 280 may be disposed on the second source/drain patterns 250. The second source/drain contacts 280 may be connected to the second source/drain patterns 250. A second contact silicide film 260 may be further disposed between the second source/drain contacts 280 and the second source/drain patterns 250.

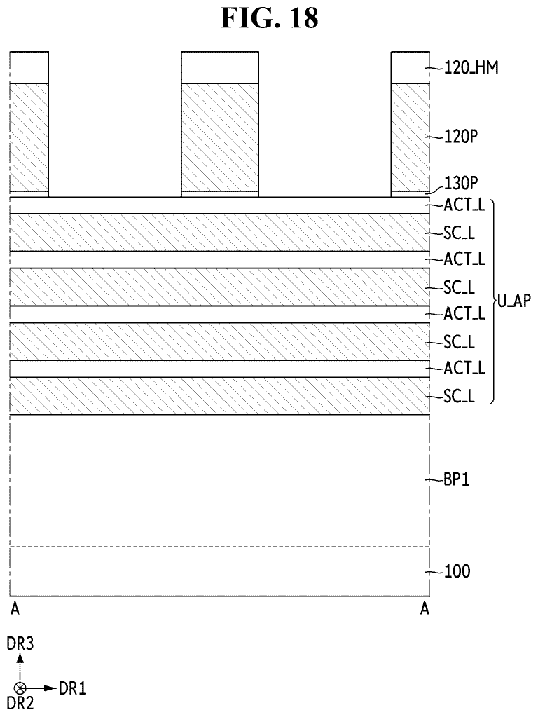

FIGS. 18 through 24 are diagrams illustrating intermediate steps of a method of manufacturing a semiconductor device according to some embodiments. For reference, FIGS. 18 through 24 may be cross-sectional views taken along line A-A of FIG. 1.

Referring to FIG. 18, a first lower pattern BP1 and an upper pattern structure U_AP may be formed on a substrate 100.

The upper pattern structure U_AP may be disposed on the first lower pattern BP1. The upper pattern structure U_AP may include a plurality of sacrificial patterns SC_L and a plurality of active patterns ACT_L that are stacked on the first lower pattern BP1, alternating with the sacrificial patterns SC_L.

For example, the sacrificial patterns SC_L may include an SiGe film. The active patterns ACT_L may include an Si film.

Thereafter, a dummy gate insulating film 130P, dummy gate electrodes 120P, and a dummy gate capping film 120_HM may be formed on the upper pattern structure U_AP. The dummy gate insulating film 130P may include, for example, silicon oxide, but the present disclosure is not limited thereto. The dummy gate electrode 120P may include, for example, polysilicon, but the present disclosure is not limited thereto. The dummy gate capping film 120_HM may include, for example, silicon nitride, but the present disclosure is not limited thereto.

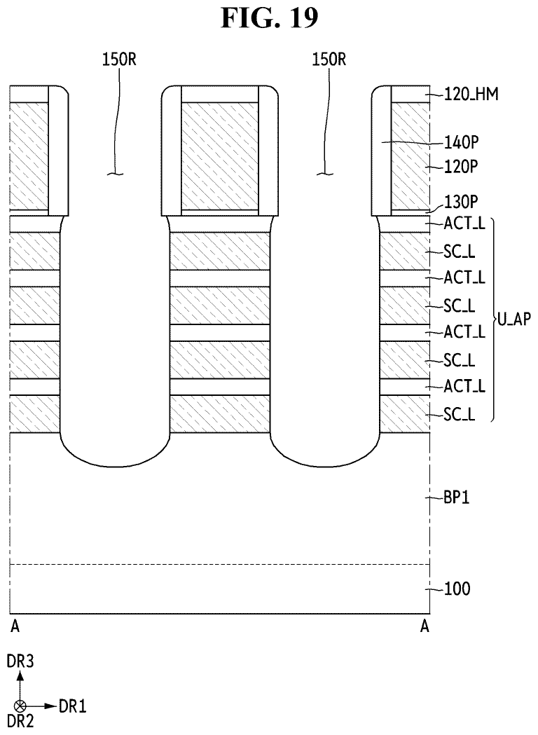

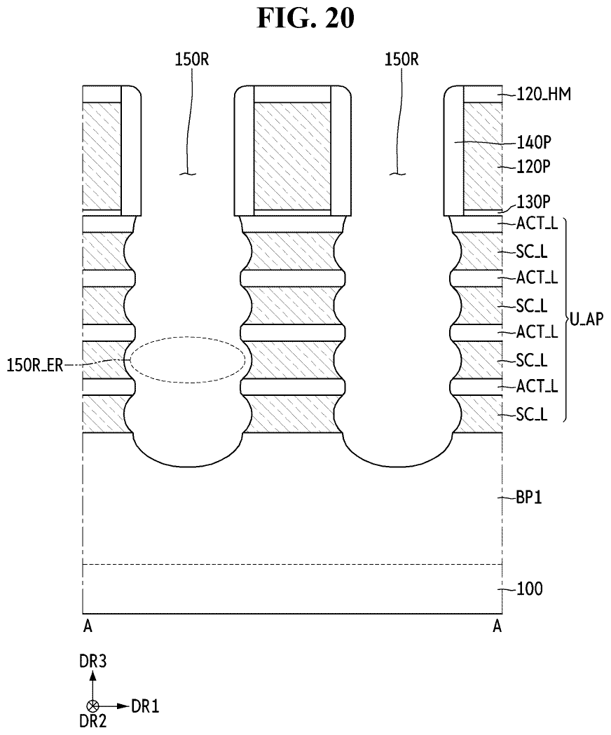

Referring to FIGS. 19 and 20, pre-gate spacers 140P may be formed on the sidewalls of the dummy gate electrodes 120P.

Using the dummy gate electrodes 120P and the pre-gate spacers 140P as a mask, first source/drain recesses 150R may be formed in the upper pattern structure U_AP.

Portions of the first source/drain recesses 150R may be formed in the first lower pattern BP1. The lower surfaces of the first source/drain recesses 150R may be defined by the first lower pattern BP1.

After forming the first source/drain recesses 150R, as illustrated in FIG. 19, the sacrificial patterns SC_L may be further etched. Through this process, first width expansion regions 150R_ER of the first source/drain recesses 150R may be formed.

The first source/drain recesses 150R may include a plurality of first width expansion regions 150R_ER. The sidewalls of the first source/drain recesses 150R may have a wavy shape. However, the method to fabricate the first source/drain recesses 150R with the first width expansion regions 150R_ER is not particularly limited.

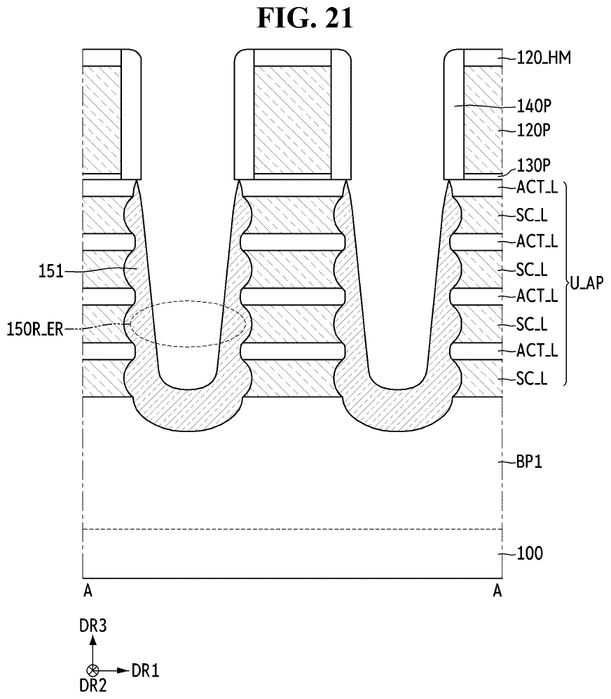

Referring to FIG. 21, a first semiconductor material film 151 is formed on the first lower pattern BP1.

The first semiconductor material film 151 may be formed along the profile of the first source/drain recesses 150R. By using an epitaxial growth method, the first semiconductor material film 151 may be formed to have a monocrystalline structure.

In some other embodiments, different from what is illustrated, before forming the first semiconductor material film 151, inner spacers (“140IN” in FIG. 14), such as those described with reference to FIGS. 13 and 14, may be formed.

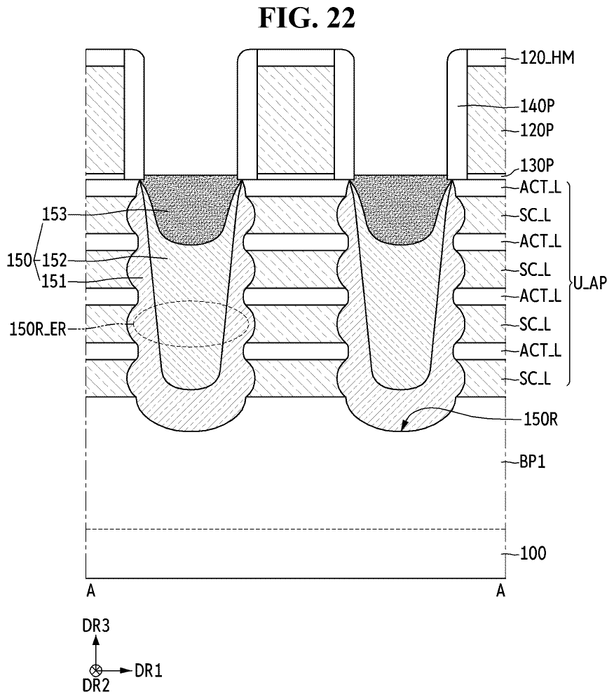

Referring to FIG. 22, a second semiconductor material film 152 may be formed on the first semiconductor material film 151.

Thereafter, a third semiconductor material film 153 may be formed on the second semiconductor material film 152. First source/drain patterns 150 may be formed within the first source/drain recesses 150R.

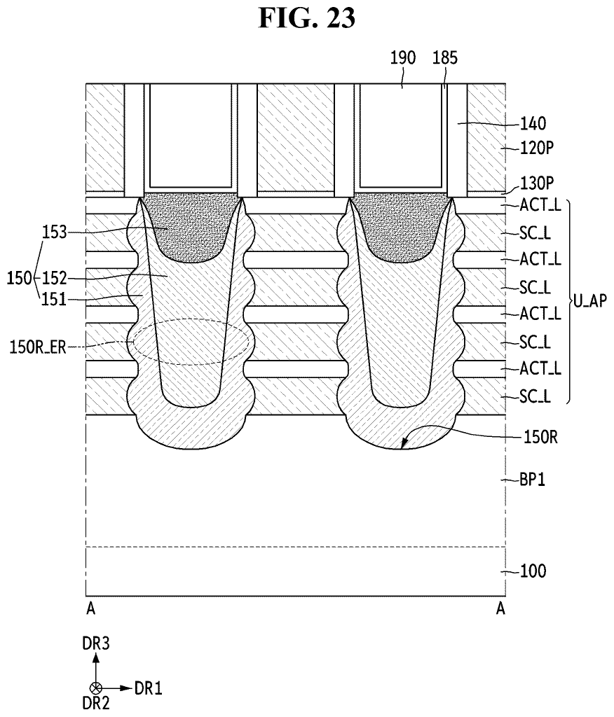

Referring to FIG. 23, a source/drain etch stop film 185 and a first interlayer insulating film 190 are sequentially formed on the first source/drain patterns 150.

Thereafter, portions of the first interlayer insulating film 190, portions of the source/drain etch stop film 185, and the dummy gate capping film 120_HM are removed, thereby exposing the upper surfaces of the dummy gate electrodes 120P. During the exposure of the upper surfaces of the dummy gate electrodes 120P, first gate spacers 140 may be formed.

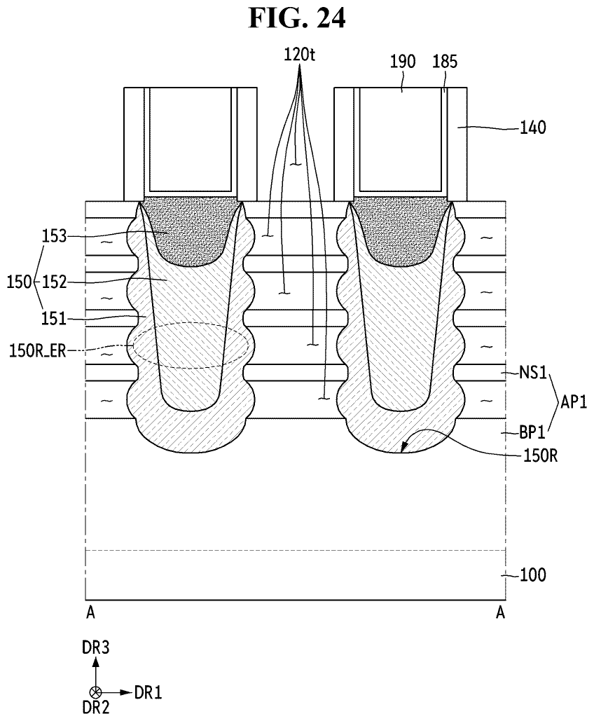

Referring to FIGS. 23 and 24, the dummy gate insulating film 130P and the dummy gate electrodes 120P may be removed, thereby exposing the upper pattern structure U_AP between the first gate spacers 140.

Thereafter, the sacrificial patterns SC_L may be removed, thereby forming first sheet patterns NS1. The first sheet patterns NS1 may be connected to the first source/drain patterns 150. Through this process, a first active pattern AP1, which includes the first lower pattern BP1 and the first sheet patterns NS1, may be formed.

Additionally, after removing the sacrificial patterns SC_L, gate trenches 120t may be formed between the first gate spacers 140. When the sacrificial patterns SC_L are removed, portions of the first source/drain patterns 150 may be exposed.

Although not illustrated, inner spacers (“140IN” in FIG. 11), such as those described with reference to FIGS. 11 and 12, may be additionally formed.

Thereafter, referring to FIG. 2, a first gate insulating film 130 and first gate electrodes 120 may be formed in the gate trenches 120t . Additionally, a first gate capping pattern 145 may be formed.

In concluding the detailed description, those skilled in the art will appreciate that many variations and modifications may be made to the example embodiments described above without substantially departing from the scope of the present disclosure. Therefore, the embodiments described above are used only for illustrative purposes and not for purposes of limitation.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms.

Rather, these terms are only used to distinguish one element from another. For example, a first element could be termed a second element, and, similarly, a second element could be termed a first element, without departing from the scope of the present disclosure. Further, as used herein, the term “and/or” includes any and all combinations of one or more of the associated listed items.

What is claimed is:

1. A semiconductor device comprising:
an active pattern on a substrate, the active pattern comprising a lower pattern that extends in a first direction parallel to an upper surface of the substrate, and a plurality of sheet patterns that are spaced apart from the lower pattern in a second direction perpendicular to the first direction;
a source/drain pattern on the lower pattern and in contact with the plurality of sheet patterns; and
a gate structure on a side of the source/drain pattern, and comprising a gate insulating film and a gate electrode,
wherein the source/drain pattern comprises a first semiconductor material film in contact with each of the plurality of sheet patterns, a second semiconductor material film on the first semiconductor material film, and a third semiconductor material film on the second semiconductor material film,
wherein the first semiconductor material film has a monocrystalline structure,
wherein the second semiconductor material film has a polycrystalline structure, and
wherein the third semiconductor material film has an amorphous structure.

2. The semiconductor device of claim 1, wherein the second semiconductor material film is between the first and third semiconductor material films.

3. The semiconductor device of claim 1, wherein the third semiconductor material film is between the first and second semiconductor material films.

4. The semiconductor device of claim 1, wherein:
the gate structure further comprises an inner gate structure between adjacent ones of the plurality of sheet patterns in the second direction, the inner gate structure comprising the gate electrode and the gate insulating film, and
the source/drain pattern is in contact with the gate insulating film of the inner gate structure.

5. The semiconductor device of claim 1, further comprising:
inner spacers between the lower pattern and at least one of the plurality of sheet patterns, and between adjacent ones of the plurality of sheet patterns in the second direction,
wherein the gate structure is in contact with the inner spacers.

6. The semiconductor device of claim 5, wherein:
the first semiconductor material film comprises sidewall portions in contact with the plurality of sheet patterns and bottom portions in contact with the lower pattern, and
the sidewall portions of the first semiconductor material film are not in contact with the bottom portions of the first semiconductor material film.

7. The semiconductor device of claim 6, wherein the inner spacers are between the sidewall portions and the bottom portions of the first semiconductor material film.

8. The semiconductor device of claim 5, wherein:
the first semiconductor material film comprises sidewall portions in contact with the plurality of sheet patterns and bottom portions in contact with the lower pattern, and
the sidewall portions of the first semiconductor material film are in contact with the bottom portions of the first semiconductor material film.

9. The semiconductor device of claim 1, wherein:
the first, second, and third semiconductor material films each comprise silicon-germanium (SiGe), and
a germanium (Ge) content in the first semiconductor material film is less than a Ge content in the second semiconductor material film and a Ge content in the third semiconductor material film.

10. The semiconductor device of claim 1, wherein the first, second, and third semiconductor material films each comprise silicon (Si).

11. A semiconductor device comprising:
an active pattern on a substrate, the active pattern comprising a lower pattern that extends in a first direction parallel to an upper surface of the substrate, and a plurality of sheet patterns that are spaced apart from the lower pattern in a second direction perpendicular to the first direction;
a source/drain pattern on the lower pattern and in contact with the plurality of sheet patterns; and
a gate structure on a side of the source/drain pattern, and comprising a gate insulating film and a gate electrode that extends in a third direction crossing the first direction,
wherein the source/drain pattern comprises a first semiconductor material film in contact with each of the plurality of sheet patterns and a second semiconductor material film on the first semiconductor material film,
wherein the first semiconductor material film has a monocrystalline structure,
wherein the second semiconductor material film has an amorphous structure, and
wherein in a cross-sectional view, the second semiconductor material film includes sidewalls that extend in the second direction.

12. The semiconductor device of claim 11, wherein:
the source/drain pattern further comprises a third semiconductor material film having a polycrystalline structure, and
the third semiconductor material film is between the first and second semiconductor material films.

13. The semiconductor device of claim 11, wherein:
the source/drain pattern further comprises a third semiconductor material film having a polycrystalline structure, and
the second semiconductor material film is between the first and third semiconductor material films.

14. The semiconductor device of claim 11, wherein the first semiconductor material film is in contact with the gate insulating film.

15. The semiconductor device of claim 11, further comprising:
inner spacers between the lower pattern and at least one of the plurality of sheet patterns, and between adjacent ones of the plurality of sheet patterns in the second direction,
wherein the gate structure is in contact with the inner spacers.

16. The semiconductor device of claim 15, wherein:
the first semiconductor material film comprises sidewall portions in contact with the plurality of sheet patterns, and
in a cross-sectional view, the sidewall portions of the first semiconductor material film comprise first sub-semiconductor patterns and second sub-semiconductor patterns that are spaced apart from the first sub-semiconductor patterns in the second direction.

17. The semiconductor device of claim 16, wherein:
the first semiconductor material film comprises bottom portions in contact with the lower pattern, and
the sidewall portions of the first semiconductor material film are not in contact with the bottom portions of the first semiconductor material film.

18. The semiconductor device of claim 15, wherein:
the first semiconductor material film comprises sidewall portions in contact with the plurality of sheet patterns and bottom portions in contact with the lower pattern, and
the sidewall portions of the first semiconductor material film are in contact with the bottom portions of the first semiconductor material film.

19. A semiconductor device comprising:
a first active pattern on a substrate, the first active pattern comprising a first lower pattern that extends in a first direction parallel to an upper surface of the substrate, and a plurality of first sheet patterns that are spaced apart from the first lower pattern in a second direction perpendicular to the first direction;
a second active pattern on the substrate, the second active pattern comprising a second lower pattern that extends in the first direction, and a plurality of second sheet patterns that are spaced apart from the second lower pattern in the second direction;
a first source/drain pattern on the first lower pattern and in contact with the plurality of first sheet patterns;
a second source/drain pattern on the second lower pattern and in contact with the plurality of second sheet patterns;
a first gate structure on a side of the first source/drain pattern; and
a second gate structure on a side of the second source/drain pattern,
wherein the first source/drain pattern comprises a first semiconductor material film in contact with each of the plurality of first sheet patterns, and a second semiconductor material film on the first semiconductor material film,
wherein the first semiconductor material film has a monocrystalline structure,
wherein the second semiconductor material film has an amorphous structure, and
wherein the second source/drain pattern has a monocrystalline structure.

20. The semiconductor device of claim 19, wherein:
the first source/drain pattern comprises an n-type dopant, and the second source/drain pattern comprises a p-type dopant.
